(19) United States
(12) Patent Application Publication
(10) Pub. No.: US 2006/0203290 A1
(43) Pub. Date: Sep. 14, 2006

(54) Method and apparatus for image processing

(75) Inventor: Shinsaku Ito, Yokohama-shi (JP)

Correspondence Address: FOLEY AND LARDNER LLP;SUITE 500, 3000 K STREET NW, WASHINGTON, DC, 20007, US

(73) Assignees: KABUSHIKI KAISHA TOSHIBA; TOSHIBA TEC KABUSHIKI KAISHA

(21) Appl. No.: 11/076,325

(22) Filed: Mar. 10, 2005

(51) Int. Cl. G03F 3/08; G06F 15/00

(52) U.S. Cl. 358/3.1; 358/1.9; 358/519

(57) ABSTRACT

In an image processing apparatus according to an embodiment of the invention, even if difference in tone reproducibility between an input resolution of an input image or a read resolution and a resolution in which an output image can be output exists during print output, the generation of the difference in tone reproducibility of the output image can be decreased in the output image.

### BACKGROUND OF THE INVENTION

1. Field of the Invention

The present invention relates to an image processing apparatus incorporated into an image forming apparatus such as an electrostatic copying machine and a laser printer. Particularly, in the image forming apparatus which outputs image output based on binarized image data, the invention relates to the image processing apparatus and image processing method which can increase tone reproducibility of an output image even if the difference in tone reproducibility exists between an input resolution and a resolution in which the output image can be output.

2. Description of the Related Art

In the electrophotographic type of copying machine, printer apparatus, and facsimile machine, a photosensitive drum charged at a predetermined potential is selectively changed by a binarized light beam in a dot shape to form an electrostatic image on the surface of the photosensitive drum. The electrostatic image is developed by supplying a developing agent (toner), and the developed image is transferred to a transferred material (output medium).

When binary data (binary scan image) is output, even in the same image, tone characteristics of the output image output to the medium is fluctuated due to the difference in resolution (input resolution) during scan. In the facsimile machine, the fluctuation in tone is also generated when the resolution on the transmission side differs from the resolution on the reception side.

For example, in the case where a decrease in image data amount is emphasized, the image (multi-level data) which is input at an arbitrary resolution for the purpose of scan (or facsimile transmission) is binarized by pseudo-gradation process represented by an error diffusion method or a dither method, and the binary image data is stored in storage means represented by a hard disk drive.

The binary image data stored in the hard disk drive is output as the output image (output) by the printer apparatus or the facsimile machine on the reception side. At this point, when the resolution which differs from the read resolution during the input or during the read on the transmission side is set, the output image output to the paper (output medium) differs from the input image in positions and density of the dots.

In order to suppress the difference in tone characteristics during the output due to the difference in input resolution, there is already proposed a method in which, before the image data is binarized, plural density conversion tables (LUT) are prepared corresponding to the input resolution (having high possibility to be input) and various density conversion tables are used according to resolution information on the input image.

In the method, the output images having the plural gradations are previously prepared, and, based on the result in which the output images are evaluated, it is necessary that the plural density conversion tables are prepared in consideration of output gradation (tone characteristics) in each input resolution having the possibility to be output. Instead of the method of preparing the plural (many) density conversion tables, it is also possible to use a parameter which changes the gradation reproducibility read from the LUT according to the input resolution.

A density adjusting processing block is prepared as a processing block which adjusts the output gradation. The density adjusting processing block changes a table parameter indicating the feature of the tone characteristics represented by a text mode, a photo mode, and the like.

In order to produce a density adjusting LUT parameter, based on the image data scanned (read) in the input resolution which can be set, the output image is output in each characteristic (mode, i.e. text mode, photo mode, and the like) of the tone characteristics, and the parameter is set so that the tone characteristics are equalized in each output image (density adjusting process).

However, even if the tone characteristics during the output are corrected by the density adjusting process, in each resolution which the image can be output, it is necessary that the tone characteristics of the output image is adjusted in each mode. Namely, the number of density adjusting parameter tables of (the number of modes) x (the number of resolutions) is required. In this case, it takes a very long time to optimize the density adjusting parameter tables. Further, because the number of parameters is increased, a storage area such as an NVRAM required to store the parameter data is also increased.

### BRIEF SUMMARY OF THE INVENTION

An object of the invention is to provide an image processing apparatus and method which can reproduce the suitable tone reproducibility in the required arbitrary resolution regardless of read conditions in reading the document information.

The invention provides an image processing apparatus comprising:

density conversion table changing means for changing density conversion table parameters applied to image data according to an input resolution or a transmission resolution, in order to adjust tone reproducibility which is changed by the input resolution or the transmission resolution when binary scan image data is printed or when facsimile transmission image data is received and output; and

density conversion table setting means for setting the density conversion table parameter in a density conversion table during inputting a scan image or during facsimile transmission.

Further, the invention provides an image processing apparatus comprising:

density conversion table changing means for changing density conversion table parameters applied to image data according to an input resolution or a transmission resolution, in order to adjust tone reproducibility which is changed by the input resolution or the transmission resolution when binary scan image data is printed or when facsimile transmission image data is received and output; and

density conversion table setting means for setting the density conversion table parameter in a density conversion table during print output or during facsimile reception.

Still further, the invention provides an image processing apparatus comprising:

density conversion table changing means for changing density conversion table parameters applied to image data according to an input resolution, in order to adjust tone reproducibility which is changed by the input resolution when binary scan image data is displayed on a monitor; and

density conversion table setting means for setting the density conversion table parameter in a density conversion table during inputting a scan image.

Moreover, the invention provides an image processing method comprising:

reading a gradation pattern in a reading device after an output device outputs the gradation pattern, the gradation pattern being converted into the arbitrary number of resolutions which the output device can output; computing tone characteristics data in each resolution; generating parameter of a table for use in density conversion based on the computed tone characteristics data in each resolution; and setting the computed parameter in a density conversion table to correct tone reproducibility corresponding to an input resolution.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a block diagram showing an image processing apparatus according to an embodiment of the invention;

FIG. 2 is a block diagram showing an image outputting apparatus according to an embodiment of the invention;

FIGS. 3A to 3C are schematic views each explaining the reason why tone reproducibility is varied when a resolution of an input image differs from a resolution of an output image;

FIG. 4A is a schematic view showing a relationship between input tone set in a γ correction unit and output density;

FIG. 4B is a schematic view showing a relationship between exposure (duty of laser) for forming the output image set in a PWM circuit and the output density; and

FIGS. 5 to 7 are schematic views each showing an example in which the image processing apparatus shown in FIG. 4B changes a “PWM” parameter.

### DETAILED DESCRIPTION OF THE INVENTION

Referring now to accompanying drawings, a preferred embodiment of the invention will be described below.

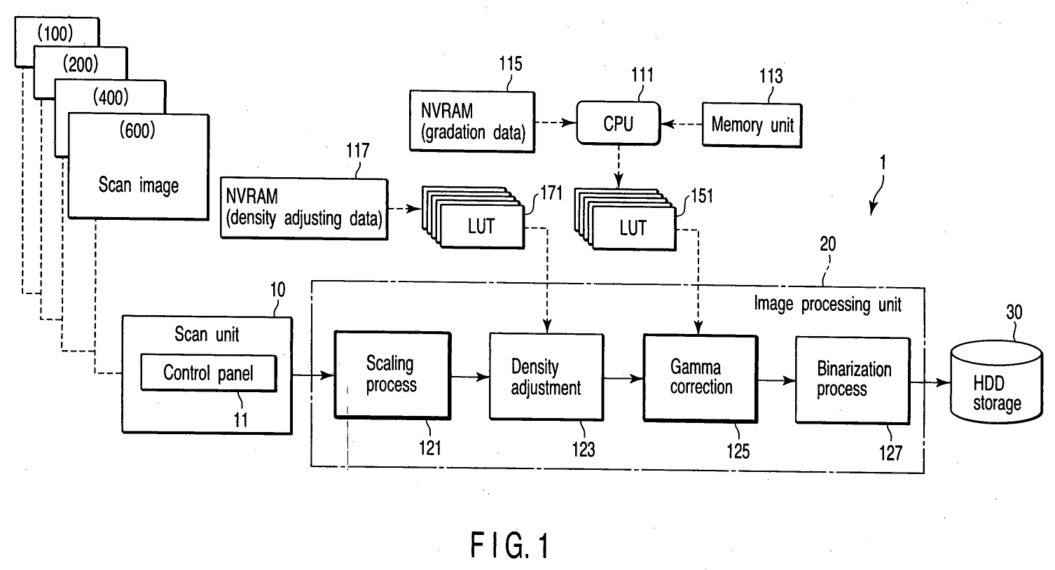

FIG. 1 shows an image processing apparatus according to an embodiment of the invention.

As shown in FIG. 1, an image processing apparatus 1 includes a scan unit 10, an image processing unit 20, and an image data storage unit 30. The scan unit 10 reads image information on a read object, i.e. the document in a form of bright and dark of the light. The image processing unit 20 processes the image information read by the scan unit 10 according to the later-mentioned rule. The image data storage unit 30 holds the image information processed by the image processing unit 20. The image processing apparatus 1 also includes a main control unit (CPU) 111 and an image memory (not shown).

The scan unit 10 includes a condition directing unit (control panel) 11. The condition directing unit 11 sets a read resolution (magnification) or a predetermined pattern in reading the image information on the read object. The read resolution or the predetermined pattern, which is input from the condition directing unit 11, is stored in a RAM (memory unit) 113 connected to the CPU 111. The CPU 111 is also connected to a non-volatile memory (NVRAM) 115 which holds tone characteristics data. The read predetermined pattern includes a density conversion parameter which is determined as an arbitrary density conversion condition.

In the image read, i.e. in reading the image information on the document with the scan unit 10, the magnification corresponding to the input resolution is set according to the resolution (X dpi) of which the condition directing unit 11 gives a direction during reading the image information (variable magnification process is performed to read image).

For example, when the read resolution is set at 600 dpi in the scanner unit 10, variable power of X/600 is set in each of the main scan direction and the sub-scan direction orthogonal to the main scan direction. In the scanner (copying machine) or the facsimile machine, the main scan direction is set to the direction in parallel with the direction in which the line sensor extends. However, for the sub-scan direction, sometimes carriage (not shown) speed of the scanner unit (or document moving speed in the facsimile machine in which the document is moved in the direction orthogonal to the direction in which the line sensor extends) is also changed according to the variable magnification.

As with the conventional image processing apparatus, for the image data to which the variable magnification process is performed (read image data), a density adjusting unit 123 performs density conversion according to the resolution of the input image referring to a density conversion table (LUT) 171 before the image data is binarized (density adjusting process). The density conversion table (LUT) 171 is held by a non-volatile memory (NVRAM) 117. The non-volatile memory (NVRAM) 117 holds density conversion adjusting data.

A γ correction unit (image processing unit) 125 performs γ correction to the image data to which the density adjusting process is performed by the density adjusting unit 123, and a binarization processing unit 127 performed the binarization to the image data. In the binarization processing unit 127, the binarization is performed by the pseudo-gradation process represented by the error diffusion method and the dither method.

When the input image resolution (after read) differs from the resolution of the image output by the output device in outputting the output image, there is no problem in the case where the image data having the input resolution of 600 dpi (dots per inch) is output in 600 dpi. However, for example, in the case where the image data having the input resolution of 600 dpi (dots per inch) is output in 300 dpi, the output image is enlarged double in both the longitudinal (main scan) direction and the crosswise (sub-scan) direction, and the output image is output while four pixels form one cluster.

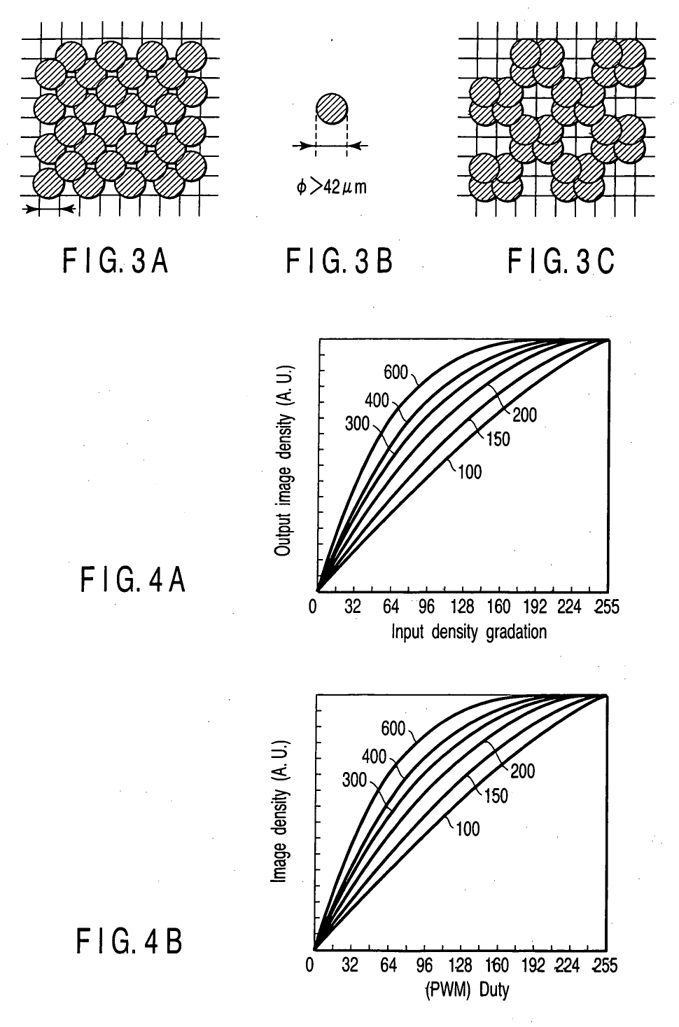

As shown in FIGS. 3A and 3C, when a size of one dot on the paper, i.e. the size of the toner image of one cluster is larger than the dot defined by the original resolution (see FIG. 3B) due to the difference in dot gain, the toner often intrudes a non-pixel portion (pixel in which the dot is not formed) from the surrounding dots. Namely, the non-pixel portion is embedded by the toner supplied from the surrounding pixels (the area of the non-pixel portion is decreased by embedding the non-pixel portion with the toner from the surrounding pixels).

In other words, as the input image resolution is increased, a toner area ratio is increased in the output image after the resolution is converted. Accordingly, when the input image having the high resolution is output, the tone characteristics often tends to shift to the high density side (density is increased).

Against this backdrop, regardless of the condition (mode) in reading (scanning) the document information, it is desirable to provide the image forming apparatus and the image processing method which can reproduce the suitable tone characteristics in an arbitrary resolution by optimizing a γ correction curve and a table used in pulse width modulation (PWM).

Therefore, in the γ correction performed by the γ correction unit 125, however not described in detail, a group of LUTs (LUT-1) 151 previously stored in NVRAM 115 is referred to. The γ correction is the parameter which is independent of the density adjusting process for the tone reproducibility represented by the text mode, the photo mode, and the like. Accordingly, the γ correction is useful for the parameter canceling printer output tone characteristics. The printer output tone characteristics are dominated by the later-mentioned density adjusting process for the tone reproducibility.

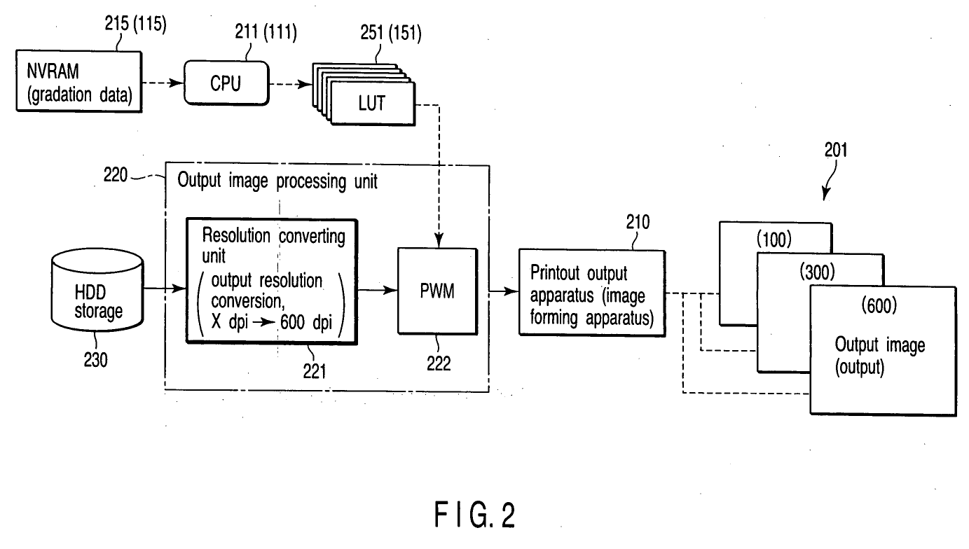

FIG. 2 shows an image forming apparatus according to the invention. The image forming apparatus shown in FIG. 2 visualizes the image data to which the image processing apparatus shown in FIG. 1 performs the image processing by a visualizing method such as the electrostatic photography process, and the image forming apparatus output the image data on a sheet of plain paper cut in a predetermined size, a transparent resin sheet for a projector, a semi-transparent sheet material for trace, and the like. The image forming apparatus of the invention can also be applied to a thermal transfer type image forming apparatus and an inkjet type image forming apparatus.

An image outputting apparatus (image forming apparatus) 201 includes an image forming unit 210 and an output image processing unit 220. For example, the electrostatic photography process is adopted for the image forming unit 210. The output image processing unit 220 supplies the image data which should be output to the image forming unit 210. A hard disk drive (image data storage unit) 230 is connected to the output image processing unit 220. The hard disk drive 230 holds the image data supplied from an external device. When the image outputting apparatus is integrated with the scan unit of the image processing apparatus shown in FIG. 1, the output image can be output based on the image data read by the scan unit. In this case, for example, the image data storage unit 30 of the image processing apparatus shown in FIG. 1 also acts as the image data storage unit 230. Therefore, the density adjusting process for the tone reproducibility can be performed to the image corresponding to the image data read by the scan unit 10.

It is also possible that the image forming apparatus (image outputting apparatus) 201 shown in FIG. 2 is integrated with the image processing apparatus shown in FIG. 1. Accordingly, when the input image resolution differs from the output image resolution, in outputting the image by performing the resolution conversion to the input image having the high resolution, the shift to the high density side (increase in density) can be suppressed in the tone reproducibility without using a density adjusting parameter table. The large storage capacity of (the number of modes)×(the number of resolutions) is required for the density adjusting parameter table.

In the image outputting apparatus 201 shown in FIG. 2, the resolution of the supplied image data is converted from X dpi which is of the input image resolution into the output image resolution (in this case, 600 dpi) by an output resolution converting unit 221 in an output image processing unit 220.

The image data in which the output resolution converting unit 221 converts the input image resolution into the output image resolution (600 dpi) is converted into laser pulse signals by a pulse width modulation (PWM) circuit 222. The laser pulse signals change laser beam energy output from an exposure device of the image forming apparatus 210.

Then, the resolution conversion by the output resolution converting unit 221 of the output image processing unit 220 will be described in detail.

The gradation pattern data, in which resolution is converted corresponding to an arbitrary input resolution to perform the binarizing process such as the error diffusion, is previously prepared. The image forming unit 210 outputs the output image using the gradation pattern data. When the output image is output corresponding to each input resolution, the plural gradation image outputs corresponding to various input resolution are obtained.

The output image output from the image forming unit 210, i.e. print out (output) corresponding to the gradation pattern is read by the scan unit 10 to obtain a read value at the corresponding gradation level. The plural gradation output images corresponding to the arbitrary input resolution are obtained by repeating the process in all the resolutions corresponding to the resolution during the input resolution (having high possibility to be input). It is possible that the input image is the data received through the facsimile machine. In this case, the data corresponding to the input resolution is the read resolution of the facsimile machine on the transmitting side.

The output in each input resolution read is stored as the tone characteristics (γ correction data) in the non-volatile memory (NVRAM) 215.

The process of capturing the output in each input resolution as the tone characteristics (γ correction data) is similar to the density adjusting process in which the scan unit 10 and the image processing unit 20 are used.

A γ correction table or a pulse width modulation (PWM) table, which corrects difference in tone characteristics, is computed for the scanned image data (stored in an HDD) by using the tone characteristics data (γ correction data) stored in NVRAM 215. Then, the γ correction table or the PWM table is set in the γ correction unit 115 or the PWM circuit 222.

Thus, the gradation pattern is read by the input device, and the print output tone characteristics in each resolution which can be input are (automatically) obtained. At this point, only the number of LUTs corresponding to the number of input resolutions (the number of kinds of input resolutions) is required by using the above-described γ correction data. The LUT is utilized for correcting the difference in tone characteristics during the output. The tone characteristics depends on the difference in input resolution.

FIG. 4A shows a relationship between the input tone set in the γ correction unit 125 and the output density.

As can be seen from FIG. 4A, for example, in the case where the output resolution of the outputting (print) unit 210 is set at 600 dpi, when the density conversion is simply performed to the image data of the resolution lower than 600 dpi, as described referring to FIG. 3C, the tendency of the non-pixel portion to be embedded by the toner supplied from the surrounding pixels (the area of the non-pixel portion is decreased by embedding the non-pixel portion with the toner from the surrounding pixels) becomes more remarkable, as the input resolution is increased. Accordingly, the output density to the (PWM) duty shows denser characteristics as a whole, as the value (100, 150, . . . , 400, and 600) indicating the resolution is increased.

FIG. 4B shows a relationship between the exposure (duty of laser) for forming the output image set in the PWM circuit 222 and the output density.

As can be seen from FIG. 4B, for example, in the case where the output resolution of the print unit (image forming unit) 210 is set at 600 dpi, when the density conversion is simply performed to the image data of the resolution lower than 600 dpi, as described referring to FIG. 3C, the tendency of the non-pixel portion to be embedded by the toner supplied from the surrounding pixel portions (the area of the non-pixel portion is decreased by embedding the non-pixel portion with the toner from the surrounding pixel portions) becomes more remarkable as the input resolution is increased. Accordingly, the output density to the (PWM) duty shows denser characteristics as a whole, as the value (100, 150, . . . , 400, and 600) indicating the resolution is increased.

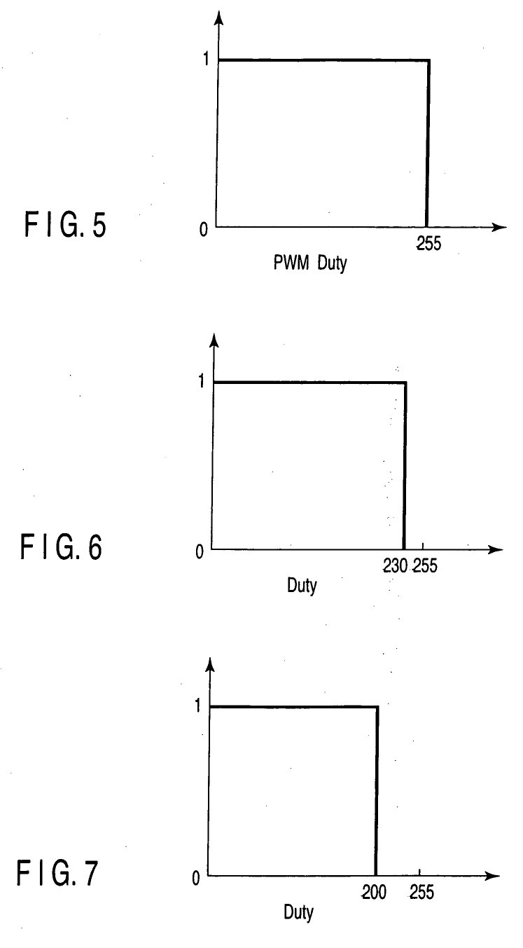

As shown in FIGS. 5 to 7, the control of the (PWM) duty means that a laser pulse width is controlled in Y/255 (in the case of eight bits). The laser pulse width has high correlation to the exposure quantity (light quantity, i.e. exposure energy) for forming one dot.

As described above, in the image processing apparatus and the image processing method of the invention, even if the difference in tone reproducibility between the input resolution of the input image (read resolution) and the resolution in which the output image can be output exists during the print output, the generation of the difference in tone reproducibility is decreased in the output image.

The density adjustment LUT set in the density adjusting unit 123 is independent according to the document mode specified by the control panel (direction unit 11), so that the output gradation reproduction in common to the resolutions independent of the processing mode can be realized.

Further, the output tone reproduction is defined such that the table for use in the density conversion corresponds to the input resolution by using the parameter generated based on the tone characteristics data in each resolution, so that it is not necessary that the density adjustment LUT parameter set in the density adjusting unit 123 is distinguished in each resolution. Therefore, the capacity of the storage unit used for the density adjustment LUT parameter can be decreased.

Accordingly, the cost reduction can be achieved in the image processing apparatus.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An image processing apparatus comprising:
density conversion table changing means for changing density conversion table parameters applied to image data according to an input resolution or a transmission resolution, in order to adjust tone reproducibility which is changed by the input resolution or the transmission resolution when binary scan image data is printed or when facsimile transmission image data is received and output; and
density conversion table setting means for setting the density conversion table parameter in a density conversion table during inputting a scan image or during facsimile transmission.

2. An image processing apparatus according to claim 1, further comprising:
a storage device which holds the parameter of the density conversion table referred to by the density conversion table changing means.

3. An image processing apparatus according to claim 1, wherein the density conversion table set by the density conversion table changing means is a table which has characteristics correcting tone characteristics, the tone characteristics being varied according to energy quantity of exposure light for use in forming a latent image in a electrostatic photography process.

4. An image processing apparatus comprising:
density conversion table changing means for changing density conversion table parameters applied to image data according to an input resolution or a transmission resolution, in order to adjust tone reproducibility which is changed by the input resolution or the transmission resolution when binary scan image data is printed or when facsimile transmission image data is received and output; and
density conversion table setting means for setting the density conversion table parameter in a density conversion table during print output or during facsimile reception.

5. An image processing apparatus according to claim 4, wherein an output tone correction table in common to each resolution is set in the parameter of the table, the output tone correction table being independent of a processing mode of which an input portion gives a direction.

6. An image processing apparatus according to claim 4, wherein the parameter of the table is a γ correction parameter which is defined based on an arbitrary input resolution.

7. An image processing apparatus according to claim 4, wherein
the parameter of the table is a pulse width modulation (PWM) parameter which is defined based on the arbitrary input resolution.

8. An image processing apparatus according to claim 4, further comprising:
a storage device in which the parameter is stored, the parameter being defined based on the arbitrary input resolution.

9. An image processing apparatus comprising:
density conversion table changing means for changing density conversion table parameters applied to image data according to an input resolution, in order to adjust tone reproducibility which is changed by the input resolution when binary scan image data is displayed on a monitor; and
density conversion table setting means for setting the density conversion table parameter in a density conversion table during inputting a scan image.

10. An image processing method comprising:
reading a gradation pattern in a reading device after an output device outputs the gradation pattern, the gradation pattern being converted into the arbitrary number of resolutions which the output device can output;
computing tone characteristics data in each resolution;
generating parameter of a table for use in density conversion based on the computed tone characteristics data in each resolution; and
setting the computed parameter in a density conversion table to correct tone reproducibility corresponding to an input resolution.

11. An image processing method according to claim 10, wherein
the parameter for use in the density conversion is previously set in each read resolution which can be input.

12. An image processing method according to claim 10, further comprising:
storing the parameter for use in the density conversion in a predetermined storage unit.
